(19) United States
(12) Patent Application Publication
(10) Pub. No.: US 2010/0327883 A1
(43) Pub. Date: Dec. 30, 2010

(54) INDUCTIVE DELTA C EVALUATION FOR PRESSURE SENSORS

(76) Inventor: Jochen REINMUTH, Reutlingen (DE)

Correspondence Address: KENYON & KENYON LLP, ONE BROADWAY, NEW YORK, NY, 10004, US

(21) Appl. No.: 12/814,160

(22) Filed: Jun. 11, 2010

(30) Foreign Application Priority Data
Jun. 24, 2009 (DE) 102009027132.5

(51) Int. Cl. G01R 27/26

(52) U.S. Cl. 324/681

(57) ABSTRACT

A measuring device has a sensor unit and an evaluation unit which is electrically isolated from the sensor unit by a partition wall. The sensor unit includes a first capacitive sensor which is electrically connected to a first coil to form a first oscillating circuit, and a reference capacitor which is electrically connected to a second coil to form a second oscillating circuit. The evaluation unit includes a third coil which is inductively coupled to the first coil and the second coil, and the evaluation unit is designed to determine and output a beat frequency of a beat signal which is inductively injected into the third coil by the first oscillating circuit and the second oscillating circuit.

### BACKGROUND INFORMATION

According to the related art, capacitive sensors are known and used, for example, as pressure sensors. Capacitive sensors form a variable electrical capacitance, which is a function of the measured variable and is evaluated by a suitable evaluation circuit. In automotive engineering, in particular, capacitive pressure sensors are used in a variety of ways. The basic conditions under which pressure is measured are becoming increasingly more aggressive. In particulate-soot filters, for example, the differential pressure is measured in the exhaust gas system. The sensor is exposed directly to the chemically aggressive gases and fluids at high temperatures. To protect the measuring device, a sensor element is therefore constructed in part from media-resistant materials, that is, from materials which are not corroded by the aggressive environment. The sensitive evaluation circuit is encapsulated and isolated from the sensor element by a partition wall. The sensor element is evaluated via an inductive coupling through the partition wall. FIG. 1 shows an example of a pressure sensor 10 which is constructed according to this principle.

The pressure sensor has a sensor chamber 18 which is connected to the environment and is isolated from a hermetically sealed chamber 19 by a partition wall 13. An evaluation unit having evaluation electronics 12 is situated in hermetically sealed chamber 19 and makes the measuring signal available over a data line 17. Sensor chamber 18 accommodates a capacitive pressure sensor 11, which is constructed according to the known principle. The pressure sensor core forms a chamber in which two electrodes 14a and 14b, which function as capacitor plates, are situated on diametrically opposed sides. In the illustrated example, electrode 14a is situated on a mechanically deformable side of the chamber, so that the distance between electrodes 14a, 14b relative to each other, and thus also the capacitance of the system, is variable according to the ambient pressure.

Electrodes 14a, 14b are each connected to diametrically opposed ends of a planar coil 15, which is illustrated in a cross-sectional view in FIG. 1. Together with capacitive pressure sensor 11, planar coil 15 forms an oscillating circuit whose resonance frequency is a function of the capacitance of the capacitor formed by electrodes 14a, 14b. The generally known formula applies to resonance frequency fₒ:

$${f}_{0} ( p ) = \frac{1}{2 π \sqrt{L \cdot C ( p )}}$$

where L represents the inductance of planar coil 15 and C(p) the pressure-dependent capacitance of the capacitor formed by electrodes 14a, 14b.

If the oscillating circuit is excited to oscillate, a sensor signal whose frequency is a measure of the pressure present in sensor chamber 18 can be read through partition wall 13 via a second planar coil 16, which is connected to evaluation electronics 12. Evaluation electronics 12 determines the frequency of the sensor signal and thus generates the measuring signal, which is output over data line 17 for further processing. The problem here is the fact that resonance frequency fₒ is very high, due to the low capacitance of pressure sensor 11 and the structurally limited inductance of the planar coil, while the pressure-dependent variation in frequency is low. In addition, the measurement can become corrupted by interferences such as variations in temperature.

### SUMMARY OF THE INVENTION

The present invention therefore introduces a measuring device having a sensor unit and an evaluation unit which is electrically isolated from the sensor unit by a partition wall. The sensor unit includes a first capacitive sensor which is electrically connected to a first coil to form a first oscillating circuit, and a reference capacitor which is electrically connected to a second coil to form a second oscillating circuit. The evaluation unit includes a third coil which is inductively coupled to the first coil and the second coil. The evaluation unit is designed to determine and output a beat frequency of a beat signal, which is inductively injected into the third coil by the first oscillating circuit and the second oscillating circuit, as a measuring signal. The present invention has the advantage that the signals injected by the first and second oscillating circuits generate a beat signal in the third coil when the resonance frequencies of the first and second oscillating circuits differ from each other by a minimal amount. Beat frequency fₛ of the beat signal follows the following formula:

fₛ=|f₁−f₂|

where f₁ and f₂ represent the resonance frequencies of the first and second oscillating circuits, respectively.

Although f₁ and f₂ may also be very high frequencies, beat frequency fₛ is equal to the difference in frequency between f₁ and f₂ and is therefore much lower and easier to evaluate by measurement. Relatively small changes in the resonance frequencies therefore produce a relatively great change in the beat frequency.

Since the structure of the reference capacitor is preferably similar to that of the capacitive sensor, the reference capacitor behaves like the capacitive sensor in the presence of interference. As a result of the difference formation, changes in the reference frequencies of the first and second oscillating circuits at least approximately cancel each other out as a result of interferences, which further improves measuring accuracy.

The capacitive sensor is particularly preferably a capacitive pressure sensor; however, the present invention is also applicable to any other type of capacitive sensor.

In a preferred specific embodiment of the present invention, the reference capacitor is designed as a second capacitive sensor, in particular as a second capacitive pressure sensor. At least two variants thereof are conceivable:

In a first variant, the first capacitive sensor and the second capacitive sensor form a differential capacitive sensor which is designed to generate a sensor signal as a difference between the capacitances of the first capacitive sensor and the second capacitive sensor. This variant forms, for example, a pressure difference sensor which is able to determine a pressure difference between two different locations. If the first and second capacitive sensors have an identical structure and are effectively thermally coupled, interferences such as those described above optimally cancel each other out. The first capacitive sensor and the second capacitive sensor should be situated in separate chambers, each of which is spatially connected to different locations in the measurement environment.

In a second variant, the first capacitive sensor and the second capacitive sensor are situated in the same chamber. The second capacitive sensor is either fixed in place so that its capacitance is independent of the measured variable, or it is designed in such a way that its characteristic is the opposite of the characteristic of the first capacitive sensor, i.e., so that changes in the measured variable affect the capacitance of the sensor in the opposite direction. In the latter case, the variable components of the resonance frequencies of the first and second oscillating circuits add up as a result of the difference formation according to the above formula for beat frequency fₛ, which increases measurement sensitivity.

The resonance frequency of the first oscillating circuit may be equal to the resonance frequency of the second oscillating circuit under predetermined environmental conditions, in particular at a predetermined pressure and/or a predetermined temperature. The predetermined environmental conditions thus define a reference point of the measuring device at which the beat frequency is zero. If the actual environmental conditions deviate from the predetermined environmental conditions, the resonance frequencies of the first and second oscillating circuits also deviate from each other, thus resulting in a corresponding beat frequency.

In a preferred specific embodiment of the measuring device, the evaluation unit may have an excitation coil which is designed to excite the first oscillating circuit and the second oscillating circuit to oscillate. This specific embodiment makes it possible to give the sensor unit a passive design, so that it is not necessary to provide an electrical conductor, which may be subjected to corrosion, or the like in the portion of the measuring device which is exposed to the chemically aggressive environment.

The evaluation unit may be designed to generate a current pulse and to output it to the excitation coil. The length of the current pulse is determined according to the resonance frequencies of the first and second oscillating circuits which are actually present in a particular measuring device. The higher the resonance frequency, the shorter the current pulse should be.

Alternatively, the excitation coil may be electrically connected to an excitation capacitor to form a third oscillating circuit, which has an active excitation. In this case, the third oscillating circuit may oscillate at its resonance frequency for a longer period of time, as a result of the active excitation, and thus excite the first and second oscillating circuits to oscillate via the inductive coupling.

In both aforementioned alternatives, the excitation coil may be the third coil. However, it is also conceivable to provide an additional excitation coil.

To determine the beat frequency, the evaluation unit may have, for example, a rectifier, a lowpass filter, and a frequency counter. The rectifier is designed to rectify the beat signal, and the lowpass filter is designed for lowpass filtering of the rectified beat signal. The frequency counter, in turn, is designed to determine a frequency of the lowpass filtered, rectified beat signal as the beat frequency. Alternatively, other evaluation circuits are conceivable, which are available to those skilled in the art according to the related art.

### BRIEF DESCRIPTION OF THE DRAWINGS

FIG. 1 shows a capacitive pressure sensor having an inductive coupling according to the related art.

FIG. 2 shows an exemplary embodiment of the present invention as a differential capacitive pressure sensor.

FIG. 3 shows sample signals for a measurement using the measuring device according to the present invention.

FIG. 4 shows a second exemplary embodiment of the present invention.

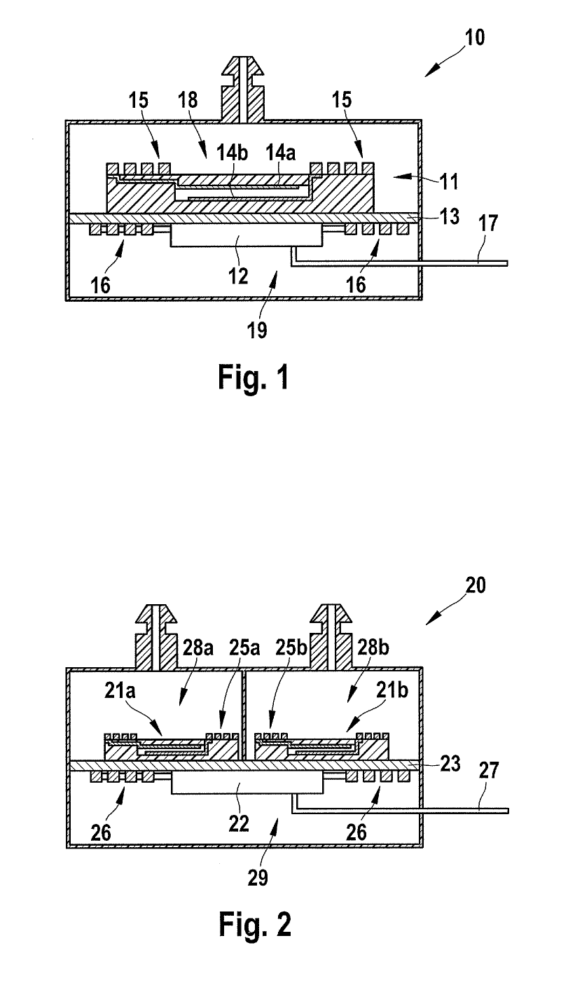

### DETAILED DESCRIPTION

FIG. 2 shows an exemplary embodiment of the present invention as differential capacitive sensor 20. Two capacitive pressure sensors 21a, 21b of a known design are situated in two sensor chambers 28a, 28b, which are isolated from each other and are each connected to different environments. Differential capacitive pressure sensor 20 is designed to measure pressure differences between the different environments. Each of the two capacitive pressure sensors 21a, 21b is surrounded by and electrically connected to a planar coil 25a, 25b to form an oscillating circuit. The two sensor chambers 28a, 28b are isolated by a partition wall 23 from a hermetically sealed chamber 29, which accommodates an electronic evaluation unit 22. Evaluation unit 22 is electrically coupled to a third planar coil 26, which is used, on the one hand, to excite planar coils 25a, 25b to oscillate and, on the other hand, to receive the oscillations generated by the oscillating circuits from capacitive pressure sensors 21a, 21b and planar coils 25a, 25b and to output these oscillations to evaluation unit 22 as a beat signal. Evaluation unit 22 determines the beat frequency of the beat signal and outputs a corresponding measuring signal over a data line 27. The beat frequency of the beat signal is a measure of the pressure difference between the two sensor chambers 28a and 28b. While sensor chambers 28a, 28b and capacitive pressure sensors 21a, 21b situated therein preferably have the same structure, this results in preferably similar electrical and thermal characteristics of the two sensor units, making it possible to ensure a high degree of measuring accuracy over a broad range of temperatures. Since only the frequency difference between the oscillations generated by the sensor units are determined according to the inventive idea, resonance frequency components of the two oscillating circuits which are dependent on temperature or other environmental conditions cancel each other out due to the difference formation.

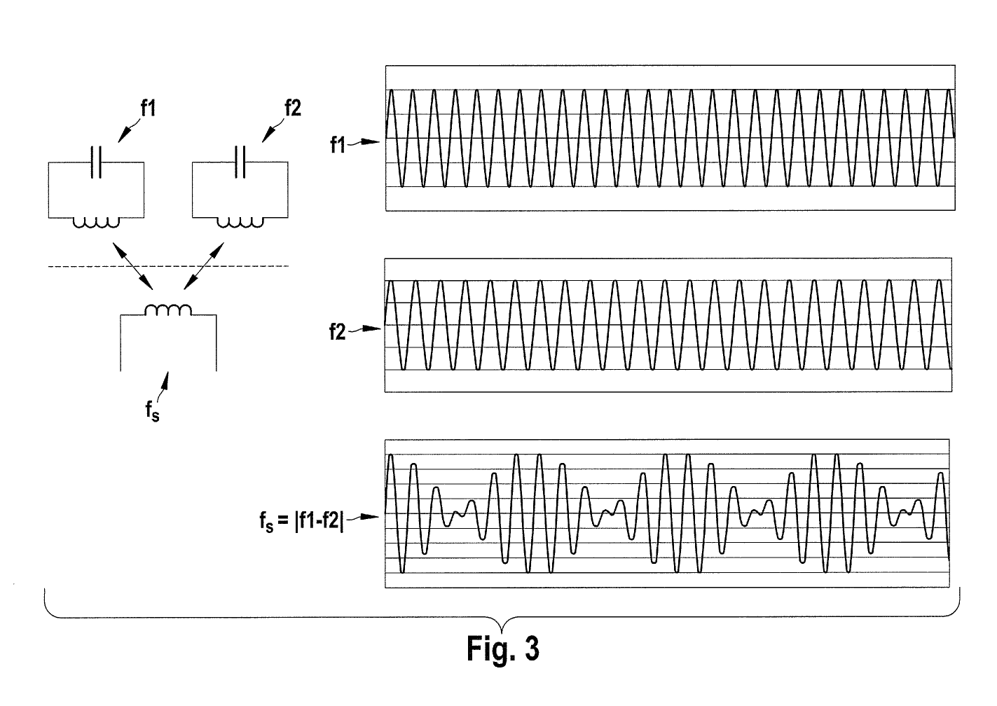

FIG. 3 shows sample signals for a measurement using the measuring device according to the present invention. A transient signal of a first oscillating circuit having a resonance frequency f₁ is plotted in a first of three partial diagrams, while a corresponding signal of a second oscillating circuit having a resonance frequency f₂ is plotted in a second partial diagram. The two resonance frequencies f₁ and f₂ in the illustrated example differ from each other by only approximately 15%. The beat signal resulting from the superimposition of the two resonance frequencies f₁ and f₂ is plotted over time in the third partial diagram. The figure clearly shows the envelope curve, which is provided with a much lower frequency and whose frequency is the beat frequency and which corresponds to the absolute value of the difference between the two resonance frequencies f₁ and f₂. Through suitable filtering, the beat frequency may be filtered out of the beat signal and then determined, in a manner similar to a demodulation of an amplitude-modulated signal.

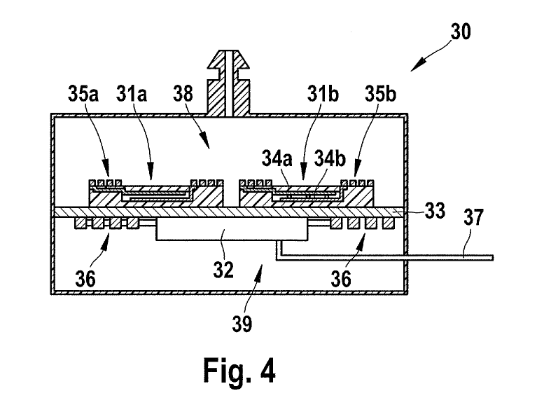

FIG. 4 shows a second exemplary embodiment 30 of the present invention. In second exemplary embodiment 30, two capacitive pressure sensors 31a and 31b are situated in the same sensor chamber 38. Capacitive pressure sensor 31b is used as a reference and has a pressure-invariable capacitance, which is achieved in the illustrated example by the fact that capacitor plates 34a, 34b of capacitive pressure sensor 31b have been mechanically blocked, preventing them from moving relative to each other. As a result, the resonance frequency of the reference oscillating circuit, generated by electrically coupling capacitive pressure sensor 31b to a planar coil 35b, is independent of pressure variations, but is still able to be influenced, for example, by temperature variations. The actual pressure measurement is carried out by capacitive pressure sensor 31a, which is coupled to an oscillating circuit by a planar coil 35a. Second exemplary embodiment 30 of the present invention permits the pressure (or any other measured variables, if other capacitive sensor types are used) to be determined in a single location, while nevertheless benefiting from the advantages of the evaluation principle according to the present invention by generating a beat between a capacitive sensor and a reference which otherwise has the same structure, but is fixed in place. Accordingly, second exemplary embodiment 30 has a hermetically sealed chamber 39, which is isolated from sensor chamber 38 by a partition wall 33 and accommodates an evaluation unit 32, which is coupled to a further planar coil 36 and is designed to determine the beat frequency of a beat generated by superimposition of the resonance frequencies of the two oscillating circuits and to output a corresponding measuring signal over a data line 37.

The principle of the present invention may also be used with other types of capacitive sensors and pressure sensors. Thus, a pressure sensor having a diaphragm system which includes two separate electrodes, in which the two separate electrodes move relative to a stationary center electrode as a function of the pressure, may be used for measuring a pressure difference. The movable electrodes are each connected to a coil to form an oscillating circuit and, together with the center electrode, form a capacitor having a pressure-variable capacitance.

This embodiment variant has the particular advantage that the pressure difference is physically formed directly via the diaphragm system. The diaphragm sensitivity may be designed specifically for the pressure difference application, independently of a high absolute pressure which may be applied. This means that the diaphragm must be only strong enough to withstand the pressure difference between two different pressures. In the embodiment illustrated in FIG. 2, on the other hand, each of capacitive pressure sensors 21a, 21b must be able to withstand the particular absolute pressure.

What is claimed is:

1. A measuring device comprising:
a sensor unit including a first capacitive sensor which is electrically connected to a first coil to form a first oscillating circuit, the sensor unit further including a reference capacitor which is electrically connected to a second coil to form a second oscillating circuit;
an evaluation unit including a third coil which is inductively coupled to the first coil and the second coil, the evaluation unit being designed to determine and output a beat frequency of a beat signal which is inductively injected into the third coil by the first oscillating circuit and the second oscillating circuit in the form of a measuring signal; and
a partition wall electrically isolating the evaluation unit from the sensor unit.

2. The measuring device according to claim 1, wherein the first capacitive sensor is a capacitive pressure sensor.

3. The measuring device according to claim 1, wherein the reference capacitor is designed as a second capacitive pressure sensor.

4. The measuring device according to claim 3, wherein the first capacitive sensor and the second capacitive sensor form a differential capacitive sensor which is designed to generate a sensor signal as a difference between capacitances of the first capacitive sensor and the second capacitive sensor.

5. The measuring device according to claim 1, wherein a resonance frequency of the first oscillating circuit is equal to a resonance frequency of the second oscillating circuit under predetermined environmental conditions, at least one of a predetermined pressure and a predetermined temperature.

6. The measuring device according to claim 1, wherein the evaluation unit includes an excitation coil which is designed to excite the first oscillating circuit and the second oscillating circuit to oscillate.

7. The measuring device according to claim 6, wherein the evaluation unit is designed to generate a current pulse and to output the current pulse to the excitation coil.

8. The measuring device according to claim 6, wherein the excitation coil is electrically connected to an excitation capacitor to form a third oscillating circuit which has an active excitation.

9. The measuring device according to claim 6, wherein the excitation coil is the third coil.

10. The measuring device according to claim 1, wherein the evaluation unit includes a rectifier, a lowpass filter and a frequency counter, the rectifier being designed to rectify the beat signal, the lowpass filter being designed for lowpass filtering of the rectified beat signal, and the frequency counter being designed to determine a frequency of the lowpass filtered, rectified beat signal as a beat frequency.
